(19) United States
(12) Patent Application Publication
(10) Pub. No.: US 2004/0102054 A1
(43) Pub. Date: May 27, 2004

(54) Method of removing edge bead during the manufacture of an integrated circuit

(76) Inventors: Michael J. Leeson, Portland, OR (US); Ebrahim Andideh, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/304,385

(22) Filed: Nov. 25, 2002

(51) Int. Cl. H01L 21/00; H01L 51/40; H01L 21/31

(52) U.S. Cl. 438/778; 438/3; 438/780; 438/782

(57) ABSTRACT

Briefly, in accordance with one embodiment of the invention, an edge bead removal process is performed during the manufacture of a ferroelectric memory device while a polymer solution is still wet.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a cross-section view of a semiconductor structure that illustrates one stage of fabrication of an embodiment of the present invention;

FIG. 2 is a cross-section view of the semiconductor structure depicted in FIG. 1 after further processing;

FIG. 3 is a cross-section view of the semiconductor structure depicted in FIG. 2 after further processing;

FIG. 4 is a cross-section view of the semiconductor structure depicted in FIG. 3 after further processing;

FIG. 5 is a cross-section view of a cross-point polymer memory cell that is the semiconductor structure depicted in FIG. 4 after further processing; and

FIG. 6 is a flow chart that describes a process in accordance with an embodiment.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

The present invention relates to a ferroelectric polymer storage devices including a ferroelectric polymer structure that is sandwiched between an array of electrodes that achieve electrical signaling across the ferroelectric polymer structure. Such storage devices may include a polymer material that may be polarized to represent various states of a memory cell, although the scope of the present invention is not limited in this respect.

It should be understood that the scope of the present invention is not limited to only those processes that result in the particular device or devices described herein. In the following example, a device is described being manufactured with a damascene flow. This is not a limitation of the scope of the present invention. In alternative embodiments other structures and/or process may be used for the electrode layers and the polymer layer. The edge bead removal process described is largely independent of how the other portions of the memory device are formed.

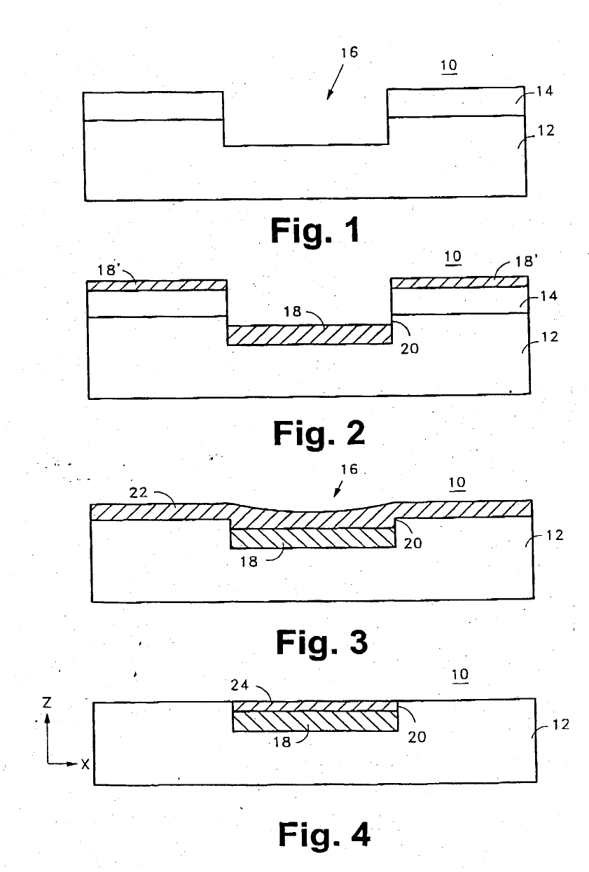

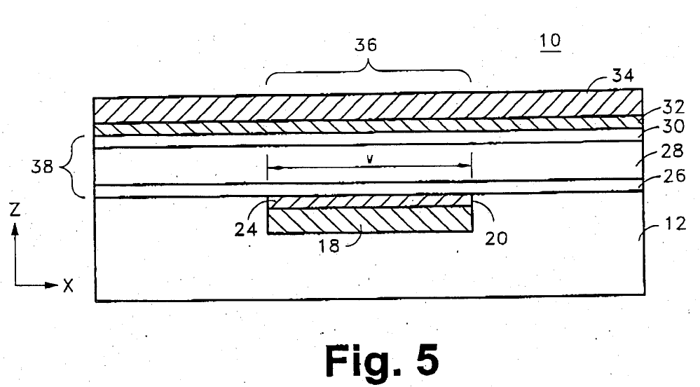

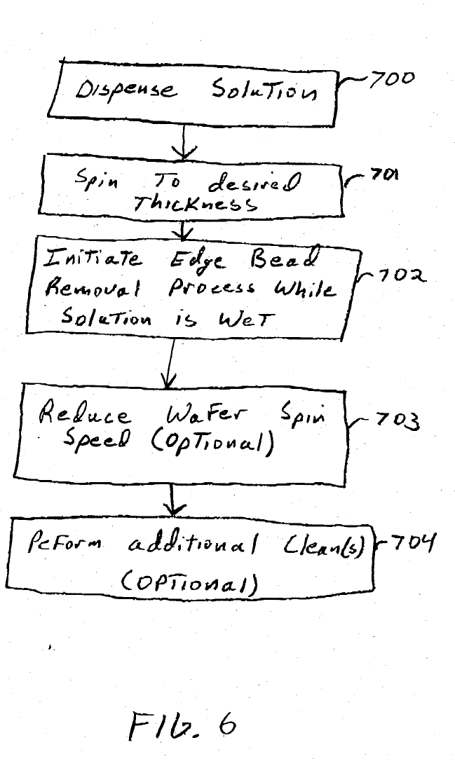

FIG. 1 is a cross-section illustration of a memory structure 10 during fabrication of a ferroelectric polymer (FEP) memory according to one embodiment. A substrate 12 is depicted as being patterned with a mask 14 and a recess 16 has been formed in substrate 12 through mask 14. Recess 16 may be prepared to accept a first or lower electrode 18 as depicted in FIG. 2. First electrode 18 may be formed by chemical vapor deposition (CVD), physical vapor deposition (PVD), sputtering, or any other alternative formation process using any material that is suitable as an electrical conductor. For example, although the scope of the present invention is not limited in this respect, first electrode 18 may comprise an aluminum material, copper or copper alloy material. The thickness of first electrode 18 (and the second electrode 34, depicted in FIG. 5) may be varied as desired. FIG. 2 also illustrates extraneous electrode material 18′ above and on mask 14, both of which may be removed.

After the formation of first electrode 18, mask 14 may be removed according to known techniques such as wet stripping, etc. In addition, extraneous electrode material 18′ depicted upon mask 14 in FIG. 2, may removed with the mask removal technique.

FIG. 3 illustrates the memory structure 10 after further processing to form a self-aligned electrode structure in accordance with a particular embodiment. A protective layer 22 may be formed over substrate 12 and first electrode 18. Protective layer 22 may be formed by CVD, PVD, atomic layer chemical vapor deposition (ALCVD), etc., although the scope of the present invention is not limited by the presence of protective layer 22 or the particular technique used to form it.

Protective layer 22 may be a metal, a refractory metal, or a metal or refractory metal alloy. Additionally, protective layer 22 may be a nitride, oxide, or carbide of the metal, refractory metal, or alloy thereof. Further, combinations of the above may be selected such as a composite protective layer. In one particular embodiment, protective layer 22 may include a titanium nitride layer, or alternatively, a titanium oxide layer, although the scope of the present invention is not limited in this respect.

FIG. 4 illustrates the memory structure 10 after further processing. Protective layer 22 may be reduced in vertical profile to leave a first or lower protective film 24 over first electrode 18. Reduction of the vertical profile may be carried out by mechanical polishing, chemical-mechanical polishing (CMP), chemical etch back, or the like. In one embodiment, CMP may be employed with a chemical recipe that is selective to substrate 12, although some reduction of the vertical profile in the Z direction may be permitted. Accordingly, a damascene structure may be formed by substrate 12, first electrode 18, and first protective film 24, although the scope of the present invention is not limited in this respect.

FIG. 5 illustrates memory structure 10 after further processing. In one embodiment, a lower layer 26, a polymer layer 28, and an upper layer 30 may be formed over substrate 12 and first protective film 24 using. Although the scope of the present invention is not limited in this respect, lower layer 26 and upper layer 30 may have a thickness ranging from about 5 to 50 angstroms, and polymer layer 28 may have a thickness ranging from about 400 angstroms to 3000 angstroms. Although it should be understood that the scope of the present invention is not limited by the thickness of the layers. Further, the scope of the present invention is not limited to memory cells that are formed with all three layers as alternative embodiments may only have one polymer layer (e.g. polymer layer 28) while other embodiments have more than three layers.

A process for forming polymer layer 28 will now be described, although is should be understood that the same or similar process may be used for the formation of lower layer 26 and upper layer 30. Polymer layer 28 may be formed from a spin on process where a solution that is dispensed over substrate 12 (i.e. dispensed onto a wafer during the manufacture of memory structure 10). The polymer or copolymer solution may include various polymers such as, but not limited to, polyvinyl and polyethylene fluorides, polyvinyledene fluoride (PVDF) polymer, copolymers thereof, and combinations thereof.

Alternatively, the solution used to provide all or a portion of the storage medium for memory structure 10 may comprise a polymer selected from polyvinyl and polyethylene chlorides, copolymers thereof, and combinations thereof; from polyacrylonitriles, copolymers thereof, and combinations thereof; from polyamides, copolymers thereof, and combinations thereof; from polyfluorides and polyamides or polyfluorides and polyacrylonitriles, and combinations thereof.

In one particular embodiment, polymer layer 28 may be formed from powder polymers such as PVDF and triflouroethylene (TrFE) that may be mixed together with a solvent, such as diethyl carbonate (DIEC) or ethyl lactate. Although it should be understood that the scope of the present invention is not limited by the particular polymer used to form polymer layer 28 or by the composition of polymer(s) and solvents in the solution that is dispensed. The solution dispensed should have sufficiently low viscosity so that the solution may flow or spread across a wafer when the wafer is spun.

In one particular embodiment this may be done by forming the solution so that it comprises at least 97.5 percent by weight of solvent.

Referring to FIG. 6, a process of dispensing the solution in accordance with a particular embodiment is described. The process may begin by dispensing the solution onto a wafer, box 700. Although the scope of the present invention is not limited in this respect, the solution to form polymer layer 28 may be dispensed while the wafer is being spun or while it is stationary. For example, the solution may be dispensed while the wafer is being spun at a rate of about 1000 to 4000 revolutions per minute (RPMs).

The spin speed of the wafer may then be adjusted to distribute the solution across the wafer to the desired thickness, box 701. For example, although the scope of the present invention is not limited in this respect, the wafer may be spun at a rate of about 500 to 5000 RPMs for about 15-40 seconds so that the solution has the desired thickness for polymer layer 28.

While the solution is still wet (i.e. has at least some fluid characteristics), an edge bead removal process may be initiated to remove any excess solution that may gather or build up along the edge region of the wafer, box 702. It may be easier or more efficient to begin the edge bead removal process while the solution is still wet. It may also be easier or more efficient to begin the flow of edge bead removal chemical simultaneaously with the dispense of the solution so that the solution is removed immediately as initially spreads into the edge region of the wafer. Although the scope of the present invention is not limited in this respect, the edge bead removal process may include dispensing a solvent such as, for example, ethyl lactate, along the edge of the wafer. The edge bead removal solvent may be dispensed while the wafer is being spun at the same or similar speed used to distribute the polymer solution (e.g. at about 2500 RPMs to 5000 RPMs). In other words, at least a portion of the edge bead removal process may occur while the layer of polymer solution is being spun to its final thickness, although the scope of the present invention is not limited in this respect.

Alternatively, the spin speed of the wafer may be reduced to about 500 revolutions per minute (RPMs) to 1100 RPMs, box 703. This may be desirable to remove all or at least a portion of the edge bead of the polymer solution while the solution is still somewhat viscous or fluid. Thus in particular embodiments, the polymer solution may be dispensed and distributed at a wafer spin speed ranging from about 2000-5000 RPMs and the edge bead solvent may be dispensed at a wafer spin speed of less than about 1500 RPMs.

In particular embodiments, it may be desirable to begin or perform at least a portion of the edge bead removal process before the polymer solution dries to the point where it is difficult to remove the edge bead with the solvent. For example, although the scope of the present invention is not limited in this respect, it may be desirable to initiate the edge bead removal process while the solution used to form polymer layer 28 comprises at least 50 percent solvent by weight. It should be understood that the scope of the present invention is not limited to applications of a particular ratio of solvent to polymer in the solution.

Alternative embodiments may include initiating an edge bead removal process while the polymer solution is in a fluid state. For example, at least a portion of the edge bead removal process may be performed with the polymer solution has a particular viscosity. Although the scope of the present invention is not limited in this respect, the edge bead removal process may begin while the polymer layer has sufficient viscosity such that the layer may be spread over the wafer by spinning the wafer. Even though the wafer is not actually spun at these speeds, the layer of polymer solution may have sufficient viscosity that it could be spread over the wafer by spinning the wafer at a speed ranging from about 700 RPMs to 4000 RPMs. Alternatively, the edge bead removal process may not be initiated until after the polymer solution has dried and is less viscous (i.e. the polymer solution would only spread if the wafer were spun at a rate of at least 2000 RPMs, 3500 RPMs, or even higher.

It should be understood that the edge bead removal process described above need not remove all of the edge bead formed by the polymer solution. Alternatively, the edge bead removal process may only be used to remove a portion, or even just a minority of the edge bead while the polymer solution is still fluid or wet. In such embodiments, it may be desirable to perform additional clean processes to sufficiently clean the edge bead and or the backside of the wafer, box 704. Such cleans may involved additional spinning of the wafer and additional edge bead removal processes with the same or different solvents.

It should be understood that in some embodiments it may be desirable to slow the wafer down and perform a partial edge bead removal before spinning the wafer to dispense the polymer solution to its desired thickness. In alternative embodiments at least a portion of the edge bead removal may be done while distributing the polymer solution. In yet other embodiments, the polymer solution may be distributed to near its final thickness before the edge bead removal process is initiated.

Returning to FIG. 5 the process for making memory cell 10 may continue with the formation of an upper protective film 32 and or an upper electrode 34 so that memory structure 10 is formed in an arrangement that may be referred to as a “cross point” 36 array that exposes FEP structure 38 between first electrode 18 and second electrode 34. In other words, the cross point 36 or projection of the width W, of first electrode 18 upward onto second electrode 34 exposes an area of FEP structure 38 that is about equivalent to the square of width W if second electrode 34 also has a width of about width W. However, it should be understood that the scope of the present invention is not limited to forming memory cell 10 in a particular arrangement or configuration. In alternative embodiments, memory structures may be formed that have more or less layers, use different structures and material to form electrodes, or have the storage medium and cells patterned in a different manner. Such alternatives may be desirable if the process to form a ferroelectric memory is integrated into a manufacturing process that also makes logic transistors (e.g. a processor that includes embedded polymer memory).

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A method of making an integrated circuit, comprising:
initiating an edge bead removal process of a layer of polyvinyledene fluoride (PVDF) polymer while the layer of PVDF polymer comprises at least 50 percent by weight of solvent.

2. The method of claim 1, wherein at least a portion of the edge bead removal process occurs while the layer of PVDF polymer is being spun to its final thickness.

3. The method of claim 1, wherein the layer of PVDF polymer is dispensed onto a wafer, and initiating the edge bead removal process begins while the wafer is spinning at rate between about 500 revolutions per minute (RPMs) and 1100 RPMs.

4. The method of claim 1, further comprising dispensing a solvent comprising ethyl lactate.

5. The method of claim 1, wherein the edge bead removal process is initiated while the layer of PVDF polymer is in a fluid state.

6. The method of claim 1, wherein the layer of PVDF polymer is dispensed onto a wafer, and initiating the edge bead removal process begins while the layer of PVDF polymer has sufficient viscosity that the layer of PVDF polymer can be spread over the wafer by spinning the wafer.

7. The method of claim 6, wherein the layer of PVDF polymer has sufficient viscosity that the layer of PVDF polymer can be spread over the wafer by spinning the wafer at a speed ranging from about 700 RPMs to 4000 RPMs.

8. The method of claim 1, further comprising dispensing the layer of PVDF polymer onto a wafer, wherein the layer of PVDF polymer is a copolymer with trifluoroethylene.

9. The method of claim 1, wherein the layer of PVDF polymer is dispensed onto a wafer, and initiating the edge bead removal process begins while the wafer is spinning at rate between about 2500 revolutions per minute (RPMs) and 5000 RPMs.

10. A method of making an integrate circuit comprising a ferroelectric polymer memory device, the method comprising:
dispensing a solution comprising copolymer onto a wafer;
spinning the wafer to distribute the solution comprising copolymer; and
removing at least a portion of the solution comprising copolymer from along an edge region of the wafer while the solution comprising copolymer is wet.

11. The method of claim 10, wherein the removing at least a portion of the solution comprising copolymer is initiated while the solution further comprises at least 50 percent solvent by weight.

12. The method of claim 10, wherein the removing at least a portion of the solution comprising copolymer is initiated while the wafer is being spun at substantially the same speed to distribute the solution comprising polymer.

13. The method of clam 10, wherein spinning the wafer to distribute the solution comprising polymer occurs at a first speed, and removing at least a portion of the solution from the edge region of the wafer occurs at a second speed, the second speed being substantially slower than the first speed.

14. The method of claim 13, wherein the first speed is at least twice as fast as the second speed.

15. The method of claim 13, wherein the first speed ranges from about 2000-5000 RPMs and the second speed is less than about 1500 RPMs.

16. The method of claim 10, wherein the removing at least a portion of the solution comprising copolymer is initiated while the solution is fluid enough such that the solution comprising copolymer will spread across the wafer if spun at a rate of at least 2000 RPMs.

17. The method of claim 10, wherein the removing at least a portion of the solution comprising copolymer is initiated while the solution is fluid enough such that the solution comprising copolymer will spread across the wafer if spun at a rate of at least 3500 RPMs.

18. A method of making storage material for a ferroelectric memory:
dispensing a solution onto a wafer, the solution comprising a polymer to provide at least a portion of the storage material for the ferroelectric memory;
spinning the wafer to distribute the solution to a desired thickness; and
initiating an edge bead removal process while the solution is wet.

19. The method of claim 18, wherein the edge bead removal process is initiated while the solution comprises at least 50 percent solvent, by weight.

20. The method of claim 18, further comprising spinning the wafer at about 1000 revolutions per minute (RPMs) during the edge bead removal process.

21. The method of claim 18, further comprising spinning the wafer after the edge bead removal process.

22. The method of claim 18, wherein initiating the edge bead removal process is initiated substantially simultaneously with dispensing the solution.
